(19) United States
(12) Patent Application Publication
(10) Pub. No.: US 2016/0359145 A1
(43) Pub. Date: Dec. 8, 2016

(54) OLED MATERIAL VACUUM THERMAL EVAPORATING MASK PLATE

(71) Applicant: Shenzhen China Star Optoelectronics Technology Co. Ltd., Shenzhen City (CN)

(72) Inventor: Youyuan Kuang, Shenzhen City (CN)

(21) Appl. No.: 14/770,088

(22) PCT Filed: Jun. 23, 2015
(86) PCT No.: PCT/CN2015/082029

§ 371 Date: Aug. 24, 2015

(30) Foreign Application Priority Data
Jun. 3, 2015 (CN) 201510299297.0

(51) Int. Cl. H01L 51/56; B05B 15/04; C23C 14/24; H01L 51/00; C23C 14/04

(52) U.S. Cl. CPC H01L 51/56; H01L 51/001; H01L 51/0011; C23C 14/042; C23C 14/24; B05B 15/045

(57) ABSTRACT

The present invention provides an OLED material vacuum thermal evaporating mask plate, comprising a mask frame (1), a quickset (3) fixed on the mask frame (1) and a mask (5) fixed on the quickset (3); the mask frame (1) comprises four edges, and the four edges surround to form an opening corresponding to the mask (5); a surface of one side of the mask frame (1) close to the mask (5) is defined to be an upper surface, and each edge of the mask frame (1) comprises a groove (11); the quickset (3) is fixed in the groove (11), and an upper surface of the quickset (3) and an upper surface of the groove (11) are in the same plane; the mask (5) is fixed on the quickset (3) with spot welding and welding spots (7) are on the quickset (3); a width of the upper of the quickset (3) is smaller than a width of the quickset (3) positioned in the groove (11). When the mask deforms and the replacement is necessary, only the quickset is extracted for polishing or is replaced. The mask frame can be repeatedly used to diminish the waste amount and to raise the availability of the mask frame. Meanwhile, the spare amount of the mask frame can be reduced to save material and production cost; the mask tension can be dispersed and passed on to the mask frame at utmost for ensuring no deformation of the quickset and the uniform stress of the mask.

### FIELD OF THE INVENTION

The present invention relates to a manufacture field of an Organic Light Emitting Diode, and more particularly to an OLED material vacuum thermal evaporating mask plate.

### BACKGROUND OF THE INVENTION

Organic Light Emitting Diode (OLED) is a flat panel display technology which has great prospects for development. It possesses extremely excellent display performance, and particularly the properties of self-illumination, simple structure, ultra thin, fast response speed, wide view angle, low power consumption and capability of realizing flexible display, and therefore is considered as the “dream display”. Meanwhile, the investment for the production equipments is far smaller than the TFT-LCD. It has been favored by respective big display makers and has become the main selection of the third generation display element of the display technology field. At present, the OLED has reached the point before mass production. With the further research and development, the new technologies constantly appear, and someday, there will be a breakthrough for the development of the OLED display elements.

The OLED comprises an anode, an organic emitting layer and a cathode sequentially formed on a substrate. The respective function material layers and the cathode metal layer are manufactured by vacuum thermal evaporating. In the vacuum chamber, the organic small molecule material is heated to be sublimated or gasified to be material vapor. Then, it deposed on the glass substrate with the opens of the metal mask (Mask). The function of the mask plate is to evaporate the OLED material on the designed locations. Therefore, the aperture location, the shape and the surface planeness of the mask plate are significantly important.

As shown in FIG. 1, the mask plate of prior art comprises a mask frame 100, a mask 200 fixed on the mask frame 100 with laser welding and welding spots 300 on the mask frame 100. After a certain usage duration of the mask, the OLED material with a certain thickness is deposed thereon, the mask can easily droop and deform with gravity, and the OLED material may block apertures or shrink the effective dimension of the apertures. After the certain usage duration, the mask needs cleaning and even replacement of a new one.

When a new mask is required for replacement, the original mask has to be separated from the mask frame. The mask is removed, and the mask frame surface is ground and polished. The original point weld location should have emboss and the mask frame surface needs to be ground to be a plane (the planeness is less than 50 micrometers)Meanwhile, in the original point weld location, the heat of welding is equivalent to a thermal process to the welding point, which can cause the hardness of the point weld location gets higher. This hardened layer also requires grinding to remove so not to influence the point weld result of the next mask. A certain thickness (0.1-1 mm) will be expended when the welding face of the mask frame is polished each time.

Under such circumstance, as shown in FIG. 2, FIG. 3, after replacing the mask many times, the mask frame 100 has been polished many times, and the thickness gradually gets thinner and the middle part droops. It does not merely affect the structure strength of the frame but a certain gap will exist between the substrate and the mask. It will influence the alignment position of the mask 200 in the evaporating apparatus, which can results in poor quality of color mixture to the OLED light emitting element. Therefore, the mask frame needs to be wasted after grinding and polishing with a certain thickness, and the mask frame needs to be conveyed to the factory having a large polishing grinder for grinding and polishing. The time is wasting. Thus, many spare mask frames are essential and the production cost increases.

### SUMMARY OF THE INVENTION

An objective of the present invention is to provide an OLED material vacuum thermal evaporating mask plate, of which the mask frame can be repeatedly used to diminish the waste amount and to raise the availability of the mask frame. Meanwhile, the spare amount of the mask frame can be reduced to save material and production cost.

For realizing the aforesaid objective, the present invention provides an OLED material vacuum thermal evaporating mask plate, comprising a mask frame, a quickset fixed on the mask frame and a mask fixed on the quickset;

the mask frame comprises four edges, and the four edges surround to form an opening corresponding to the mask; a surface of one side of the mask frame close to the mask is defined to be an upper surface, and each edge of the mask frame comprises a groove;

the quickset is fixed in the groove, and an upper surface of the quickset and an upper surface of the groove are in the same plane; the mask is fixed on the quickset with spot welding and the welding spots are on the quickset;

a width of the upper surface of the quickset is smaller than a width of quickset positioned in the groove.

The groove is positioned in the middle of each edge of the mask frame, and the groove is dented at the upper surface of the mask frame;

At least two first through holes are provided under each groove, and a first screw hole corresponding to the first through hole is provided to the quickset; a first screw nail penetrates the first through hole and is latched inside the first screw hole to fix the quickset inside the groove.

The groove is positioned in the periphery of each edge of the mask frame, and the groove is formed between the upper surface and an outer surface of the mask frame.

At least two first through holes are provided under each groove, and a first screw hole corresponding to the first through hole is provided to the quickset; at least two second through holes are provided in the width direction to each quickset, and a second screw hole corresponding to the second through hole is provided at the lateral side of the groove; a first screw nail penetrates the first through hole and is latched inside the first screw hole, and a second screw nail penetrates the second through hole and is latched inside the second screw hole to fix the quickset inside the groove.

The quickset and the groove form a tight fit in dimension.

A sectional shape of the quickset is a polygon or a polygon having an arc.

The sectional shape of the quickset is a trapezoid.

Both materials of the quickset and the mask frame are metal.

The present invention further provides an OLED material vacuum thermal evaporating mask plate, comprising a mask frame, a quickset fixed on the mask frame and a mask fixed on the quickset;

the mask frame comprises four edges, and the four edges surround to form an opening corresponding to the mask; a surface of one side of the mask frame close to the mask is defined to be an upper surface, and each edge of the mask frame comprises a groove;

the quickset is fixed in the groove, and an upper surface of the quickset and an upper surface of the groove are in the same plane; the mask is fixed on the quickset with spot welding and the welding spots are on the quickset;

a width of the upper surface of the quickset is smaller than a width of the quickset positioned in the groove;

wherein the groove is positioned in the middle of each edge of the mask frame, and the groove is dented at the upper surface of the mask frame;

wherein the quickset and the groove form a tight fit in dimension;

wherein both materials of the quickset and the mask frame are metal.

The benefits of the present invention are: in the OLED material vacuum thermal evaporating mask plate provided by the present invention, grooves are respectively located on the four edges of the mask frame, and the quickset is fixed in the grooves, and the mask is fixed on the quickset by point weld; when the mask deforms and the replacement is necessary, only the quickset is extracted for polishing but it will be not necessary to convey the entire mask frame to the factory having a large polishing grinder for grinding and polishing. The operation is simple and time saving. It can be prevented that the thickness of the mask frame gets thinner caused by polishing and the mask frame has to be wasted due to many times of polishing the mask frame; when the quickset has been implemented with polishing many times and the thickness becomes unqualified, it will be alright to replace only the quickset but not waste the entire mask frame. Thus, the mask frame can be repeatedly used to diminish the waste amount and to raise the availability of the mask frame. Meanwhile, the spare amount of the mask frame can be reduced and few spare quicksets are enough to save material and production cost; the width of the upper surface of the quickset is smaller than the width of the quickset positioned in the groove; thus, the mask tension is dispersed and passed on to the mask frame at utmost for ensuring no deformation of the quickset and the uniform stress of the mask.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural diagram of an OLED material vacuum thermal evaporating mask plate according to prior art;

FIG. 2 is a sectional structure diagram of an OLED material vacuum thermal evaporating mask plate according to prior art in a normal condition;

FIG. 3 is a sectional structure diagram of an OLED material vacuum thermal evaporating mask plate according to prior art after many time polishing;

FIG. 4 is a top view diagram of an OLED material vacuum thermal evaporating mask plate according to the first embodiment of the present invention;

FIG. 5 is a top view diagram of a mask frame and a quickset in an OLED material vacuum thermal evaporating mask plate according to the first embodiment of the present invention;

FIG. 6 is a sectional diagram corresponding to a first through hole in an OLED material vacuum thermal evaporating mask plate according to the first embodiment of the present invention;

FIG. 7 is a top view diagram of a mask frame and a quickset in an OLED material vacuum thermal evaporating mask plate according to the second embodiment of the present invention;

FIG. 8 is a sectional diagram corresponding to a first through hole and a second through hole in an OLED material vacuum thermal evaporating mask plate according to the second embodiment of the present invention.

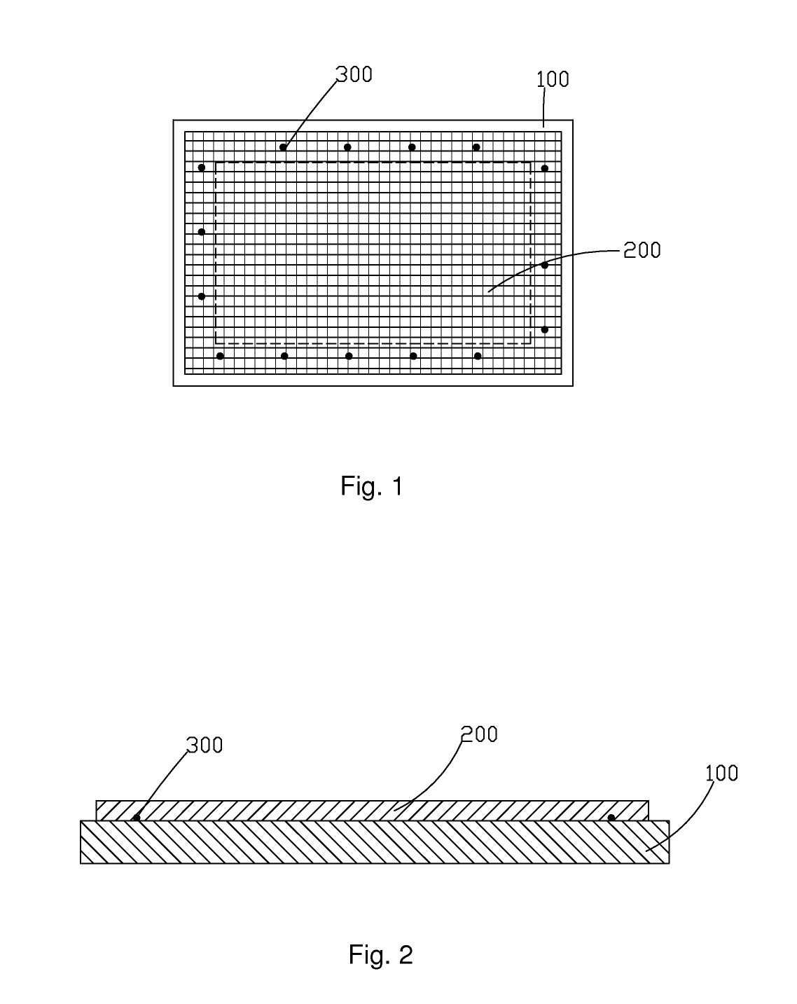

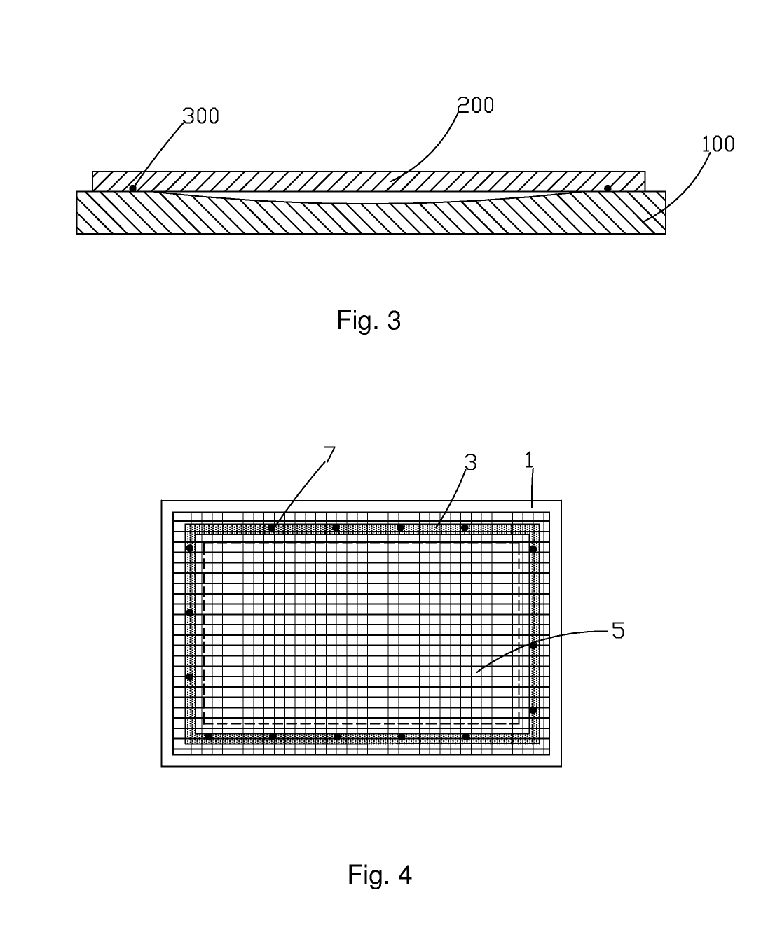

### DETAILED DESCRIPTION OF PREFERRED EMBODIMENTS

For better explaining the technical solution and the effect of the present invention, the present invention will be further described in detail with the accompanying drawings and the specific embodiments.

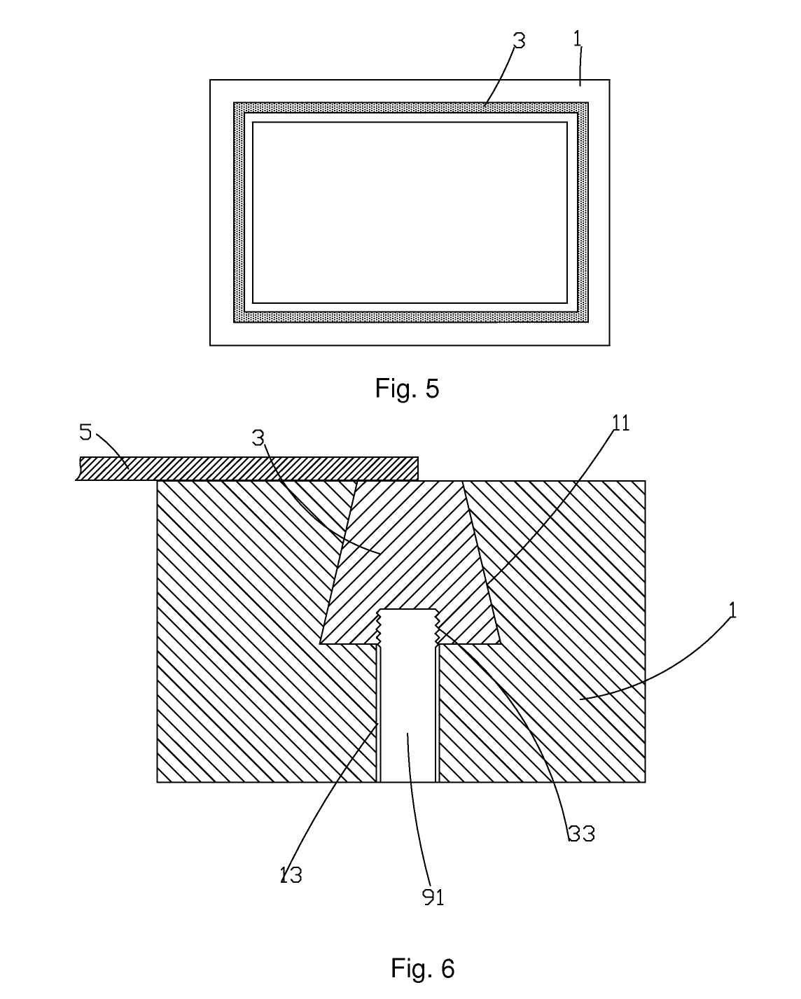

Please refer to FIG. 4 to FIG. 6. The present invention provides a first embodiment of an OLED material vacuum thermal evaporating mask plate, comprising a mask frame 1, a quickset 3 fixed on the mask frame 1 and a mask 5 fixed on the quickset 3;

the mask frame 1 comprises four edges, and the four edges surround to form an opening corresponding to the mask 5; a surface of one side of the mask frame 1 close to the mask 5 is defined to be an upper surface, and each edge of the mask frame 1 comprises a groove 11;

the quickset 3 is fixed in the groove 11, and an upper surface of the quickset 3 and an upper surface of the groove 11 are in the same plane; the mask 5 is fixed on the quickset 3 with spot welding and welding spots 7 are on the quickset 3;

Specifically, a width of the upper surface of the quickset 3 is smaller than a width of the quickset 3 positioned in the groove 11. Thus, the tension of the mask 5 welded on the quickset 3 can be dispersed and passed on to the mask frame 1 at utmost for ensuring no deformation of the quickset 3 and the uniform stress of the mask 5.

Specifically, the shape of the quickset 3 is adapted to the inner space of the groove 11, and the quickset 3 and the groove 11 form a tight fit in dimension.

Specifically, the groove 11 is positioned in the middle of each edge of the mask frame 1, and the groove 11 is dented at the upper surface of the mask frame 1.

At least two first through holes 13 are provided under each groove 11, and a first screw hole 33 corresponding to the first through hole 13 is provided to the quickset 3; a first screw nail 91 penetrates the first through hole 13 and is latched inside the first screw hole 33 to fix the quickset 3 inside the groove 11.

Specifically, a sectional shape of the quickset 3 is a polygon or a polygon having an arc.

Preferably, in the first embodiment, the sectional shape of the quickset 3 is a trapezoid.

Specifically, both materials of the quickset 3 and the mask frame 1 are metal.

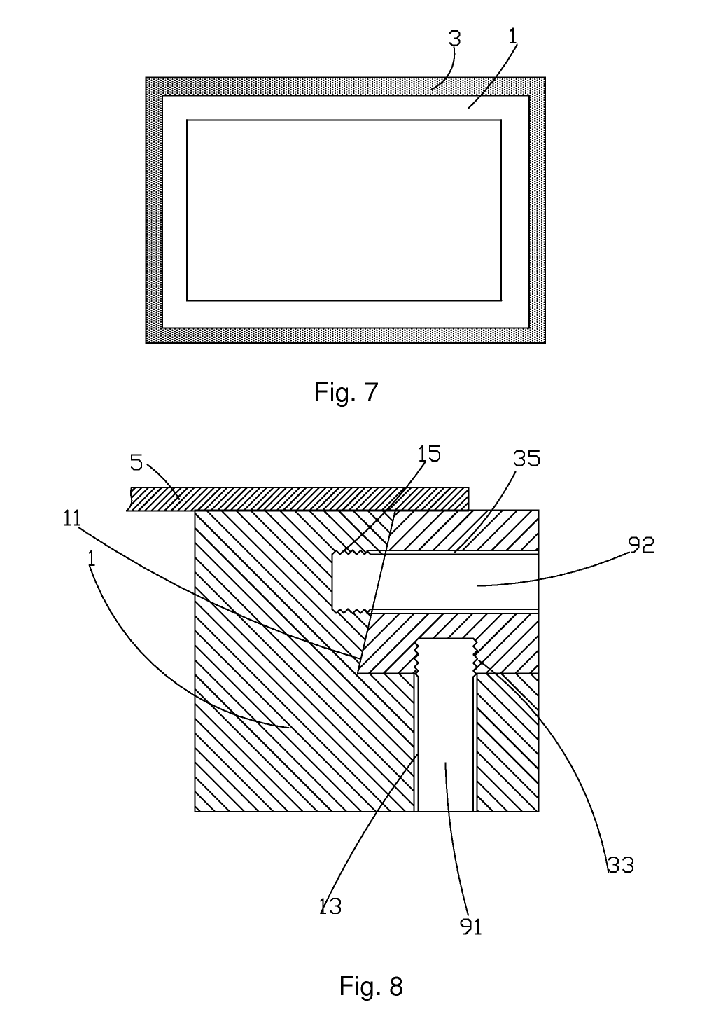

Please refer to FIG. 7 to FIG. 8 at the same time, which are structural diagrams of an OLED material vacuum thermal evaporating mask plate according to the second embodiment of the present invention. The difference from the first embodiment is that, the groove 11 is positioned in the periphery of each edge of the mask frame 1, and the groove 11 is formed between the upper surface and an outer surface of the mask frame 1; the quickset 3 is positioned at the periphery of the mask frame 1 and is convenient for installation and remove.

In the embodiment, the outer side of the quickset is not limited by the mask frame main body. Therefore, beside being fixed from the lower side, the fixture from the lateral side is also required to enhance the fixture. Thus, at least two first through holes 13 are provided under each groove 11, and a first screw hole 33 corresponding to the first through hole 13 is provided to the quickset 3; at least two second through holes 35 are provided in the width direction to each quickset 3, and a second screw hole 15 corresponding to the second through hole 35 is provided at the lateral side of the groove 11; a first screw nail 91 penetrates the first through hole 13 and is latched inside the first screw hole 33, and a second screw nail 92 penetrates the second through hole 35 and is latched inside the second screw hole 15 to fix the quickset 3 inside the groove 11.

With the aforesaid structure, as the mask 5 deforms and needs to be replaced, only the quickset 3 has to be extracted for polishing process but it will be not necessary to convey the entire mask frame 1 to the factory having a large polishing grinder for grinding and polishing. The operation is simple and time saving. It can be prevented that the thickness of the mask frame 1 gets thinner caused by polishing and the mask frame 1 has to be wasted due to many times of polishing the mask frame 1; when the quickset 3 has been implemented with polishing many times and the thickness becomes unqualified, it will be alright to replace only the quickset 3 but not waste the entire mask frame 1. Thus, the mask frame 1 can be repeatedly used to diminish the waste amount of the mask frame 1 to extend the usage cycle of the mask frame and to raise the availability of the mask frame 1 for saving the material and production cost; the width of the upper surface of the quickset 3 is smaller than the width of the quickset 3, and thus, the tension of the mask 5 can be dispersed and passed on to the mask frame 1 at utmost for ensuring no deformation of the quickset 3 and the uniform stress of the mask 5.

The aforesaid OLED material vacuum thermal evaporating mask plate is applied in the evaporation of OLED organic material and inorganic material, such as Lithium Fluoride (LiF).Certainly, the mask plate can be applied in other vacuum thermal evaporations.

In conclusion, in the OLED material vacuum thermal evaporating mask plate provided by the present invention, grooves are respectively located on the four edges of the mask frame, and the quickset is fixed in the grooves, and the mask is fixed on the quickset by point weld; when the mask deforms and the replacement is necessary, only the quickset is extracted for polishing but it will be not necessary to convey the entire mask frame to the factory having a large polishing grinder for grinding and polishing. The operation is simple and time saving. It can be prevented that the thickness of the mask frame gets thinner caused by polishing and the mask frame has to be wasted due to many times of polishing the mask frame; when the quickset has been implemented with polishing many times and the thickness becomes unqualified, it will be alright to replace only the quickset but not waste the entire mask frame. Thus, the mask frame can be repeatedly used to diminish the waste amount and to raise the availability of the mask frame. Meanwhile, the spare amount of the mask frame can be reduced and few spare quicksets are enough to save material and production cost; the width of the upper surface of the quickset is smaller than the width of the quickset positioned in the groove; thus, the mask tension is dispersed and passed on to the mask frame at utmost for ensuring no deformation of the quickset and the uniform stress of the mask.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED material vacuum thermal evaporating mask plate, comprising a mask frame, a quickset fixed on the mask frame and a mask fixed on the quickset;
the mask frame comprises four edges, and the four edges surround to form an opening corresponding to the mask; a surface of one side of the mask frame close to the mask is defined to be an upper surface, and each edge of the mask frame comprises a groove;
the quickset is fixed in the groove, and an upper surface of the quickset and an upper surface of the groove are in the same plane; the mask is fixed on the quickset with spot welding and the welding spots are on the quickset;
a width of the upper surface of the quickset is smaller than a width of quickset positioned in the groove.

2. The OLED material vacuum thermal evaporating mask plate according to claim 1, wherein the groove is positioned in the middle of each edge of the mask frame, and the groove is dented at the upper surface of the mask frame.

3. The OLED material vacuum thermal evaporating mask plate according to claim 2, wherein at least two first through holes are provided under each groove, and a first screw hole corresponding to the first through hole is provided to the quickset; a first screw nail penetrates the first through hole and is latched inside the first screw hole to fix the quickset inside the groove.

4. The OLED material vacuum thermal evaporating mask plate according to claim 1, wherein the groove is positioned in the periphery of each edge of the mask frame, and the groove is formed between the upper surface and an outer surface of the mask frame.

5. The OLED material vacuum thermal evaporating mask plate according to claim 4, wherein at least two first through holes are provided under each groove, and a first screw hole corresponding to the first through hole is provided to the quickset; at least two second through holes are provided in the width direction to each quickset, and a second screw hole corresponding to the second through hole is provided at the lateral side of the groove; a first screw nail penetrates the first through hole and is latched inside the first screw hole, and a second screw nail penetrates the second through hole and is latched inside the second screw hole to fix the quickset inside the groove.

6. The OLED material vacuum thermal evaporating mask plate according to claim 1, wherein the quickset and the groove form a tight fit in dimension.

7. The OLED material vacuum thermal evaporating mask plate according to claim 6, wherein a sectional shape of the quickset is a polygon or a polygon having an arc.

8. The package method of the OLED panel according to claim 7, wherein the sectional shape of the quickset is a trapezoid.

9. The OLED material vacuum thermal evaporating mask plate according to claim 1, wherein both materials of the quickset and the mask frame are metal.

10. An OLED material vacuum thermal evaporating mask plate, comprising a mask frame, a quickset fixed on the mask frame and a mask fixed on the quickset;
the mask frame comprises four edges, and the four edges surround to form an opening corresponding to the mask; a surface of one side of the mask frame close to the mask is defined to be an upper surface, and each edge of the mask frame comprises a groove;
the quickset is fixed in the groove, and an upper surface of the quickset and an upper surface of the groove are in the same plane; the mask is fixed on the quickset with spot welding and the welding spots are on the quickset;
a width of the upper surface of the quickset is smaller than a width of the quickset positioned in the groove;
wherein the groove is positioned in the middle of each edge of the mask frame, and the groove is dented at the upper surface of the mask frame;
wherein the quickset and the groove form a tight fit in dimension;
wherein both materials of the quickset and the mask frame are metal.

11. The OLED material vacuum thermal evaporating mask plate according to claim 10, wherein at least two first through holes are provided under each groove, and a first screw hole corresponding to the first through hole is provided to the quickset; a first screw nail penetrates the first through hole and is latched inside the first screw hole to fix the quickset inside the groove.

12. The OLED material vacuum thermal evaporating mask plate according to claim 10, wherein a sectional shape of the quickset is a polygon or a polygon having an arc.

13. The package method of the OLED panel according to claim 12, wherein the sectional shape of the quickset is a trapezoid.
